(19) United States
(12) Patent Application Publication
(10) Pub. No.: US 2006/0087378 A1
(43) Pub. Date: Apr. 27, 2006

(54) Preamplifier circuit having a variable feedback resistance

(76) Inventor: Hiroshi Hayakawa, Saitama Pref. (JP)

Correspondence Address: KAPLAN GILMAN GIBSON & DERNIER L.L.P., 900 ROUTE 9 NORTH, WOODBRIDGE, NJ, 07095, US

(21) Appl. No.: 10/973,942

(22) Filed: Oct. 26, 2004

(51) Int. Cl. H03F 3/08; H03F 1/36

(52) U.S. Cl. 330/308; 330/86

(57) ABSTRACT

A preamplifier circuit is provided in which the feedback resistance is controllably variable according to the output signal. In particular, when the output is saturated, the resistance is decreased to a smaller value by adding a parallel resistor to the feedback resistance to lower the output to below the saturation, but the resistance remains at a larger value if the output is not too large so as to keep a high signal-to-noise (SN). In a preferred embodiment, the feedback resistance can be altered such that the output always reaches a predetermined maximum value.

### BACKGROUND OF THE INVENTION

The present invention relates to an amplifier circuit, and more specifically, to a preamplifier circuit typically used in an optical receiver, such as a barcode scanner, for pre-amplifying a photocurrent generated by a photo detector such as a photodiode.

A two-stage preamplifier circuit used in an optical receiver such as a barcode reader or scanner generally comprises three blocks of circuits as illustrated in FIG. 1. Block 1 is a circuit for converting a photocurrent 11 generated by a photodiode PD into a voltage output 15. Block 2 is a circuit for rejecting low frequency noise such as an ambient light. Block 3 is a circuit for differentiating and amplifying the output 15 from the Block 1 to generate a final output 14 of the preamplifier circuit for further processing in subsequent stages.

In Block 1, the photodiode PD receives a light signal (shown as double arrows) and generates the photodiode current 11 as an input signal to a first stage amplifier OP1. A feedback resistance (implemented as a resistor R1) is connected in parallel to the amplifier OP1 so as to realize a high gain of the amplifier OP1. To generate a reliable output 15, the signal-to-noise (SN) of the amplifier circuit in Block 1 must be relatively large, for example, more than 20 dB.

The feedback resistance is a major source of undesirable noise, and it is well-known that increasing the value R of the feedback resistance is necessary to improve the signal to noise ration. However, in the design of the preamplifier circuit as illustrated in FIG. 1, the value R of the feedback resistance is limited by a maximum input signal 11, because a large resistance R implies that a high gain will result. In situations wherein the input signal is too high, such a high gain could result in the amplifier OP1 operating in the saturation region. This situation is undesirable, as the amplifier then ceases to operate as a linear gain device.

Therefore, the feedback resistance is often not optimum as to a small input signal because the resistance has to be low enough to ensure that the amplifier will not saturate when the input signal is high. The problem is particularly pronounced when the input signal varies over a large dynamic range. For example, the input signal is much larger when a barcode reader or scanner is close to the barcode or a bright light (such as sunlight) enters the barcode reader, than when the scanner reads the barcode at a distance. Thus, the relatively small value of the feedback resistance decided according to the possible maximum input signal limits the barcode reading distance because of the need for a sufficient signal-to-noise (SN) ratio.

### SUMMARY OF THE INVENTION

It is therefore an object of the present invention to provide a preamplifier circuit which has optimum signal-to-noise (SN) ratio for an input signal variable in a wide range.

Another object of the present invention is to provide a preamplifier circuit which has acceptable signal-to-noise (SN) when the input signal is small, and which also does not saturate when the input signal is large.

A further object of the present invention is to provide a method for amplifying an input signal by a preamplifier circuit with an optimum or acceptable signal-to-noise (SN).

According to an aspect of the present invention, a preamplifier circuit is provided for amplifying an input signal. A feedback resistance is connected to the amplifier in parallel, wherein a value of said feedback resistance is controllably variable, preferably according to level of input signal expected or measured. Thus, the value of the feedback resistance (and therefore the gain) can be decreased to avoid saturation when the input signal is large, but can remain a relatively large value to keep a sufficient signal-to-noise (SN) ratio when the input signal is small.

In a preferred embodiment, the feedback resistance comprises a first resistor and a second resistor, and the second resistor is connected in parallel to the first resistor through a normally-off switch which is turned on only when the output signal reaches a predetermined threshold. Thus, when the input signal is small, the feedback resistance remains at the larger value to obtain a high signal-to-noise (SN); however, when the input signal is large, the feedback resistance is changed to a smaller value so as to decrease the gain of the amplifier, preventing the amplifier from operating in a saturated mode. It is noted that when the input signal is large, the SN is still kept at an acceptable level because of the large input signal, even though the noise increases because of the smaller value of the feedback resistance.

In another preferred embodiment, the feedback resistance is implemented as a single variable resistor, the value of which is controllably altered such that the output signal is substantially equal to a predetermined maximum value. The variance of resistance value may be incrementally stepped or continuous.

According to another aspect of the present invention, a method for amplifying an input signal is provided which comprises the steps of receiving the input signal at an amplifier to generate a first output signal, comparing the first output signal with a reference to decide whether it meets a predetermined requirement, and if not, altering a value of a feedback resistance and receiving the input signal at the amplifier again to generate a new output signal. Thus, the value of the feedback resistance can be adjusted according to the output signal magnitude observed, so as to realize an optimum performance of the amplifier circuit.

In a preferred embodiment, the value of the feedback resistance is changed from a larger value to a smaller value when the first output signal reaches or is larger than the reference. Preferably, the feedback resistance comprises a first resistor and a second resistor connected to the first resistor in parallel through a switch, and the changing of the value of the feedback resistance is done by turning on the switch so as to connect the second resistor to the first resistor.

In another preferred embodiment, the value of the feedback resistance is changed such that the new output signal will be substantially equal to the reference.

In another preferred embodiment, one or more scans of the signal to be read are first performed to calibrate the system, more specifically, by determining whether to switch in a second resistor, or how to vary a variable resistor. Then, one or more actual scans are performed to read the symbol.

### DESCRIPTION OF THE DRAWINGS

The above and other features and advantages will become clearer by reading the following detailed descriptions of the preferred embodiments of the present invention with reference to the accompanying drawings, in which:

FIG. 1 is a conventional preamplifier circuit in the prior art;

FIG. 2a is a first embodiment of the preamplifier circuit according to the present invention;

FIG. 2b is a block chart illustrating the operation of the preamplifier circuit in FIG. 2a;

FIG. 3a is a second embodiment of the preamplifier circuit according to the present invention; and

FIG. 3b is a block chart illustrating the operation of the preamplifier circuit in FIG. 3a.

### DETAILED DESCRIPTION OF THE PREFERRED EMBODIMENTS

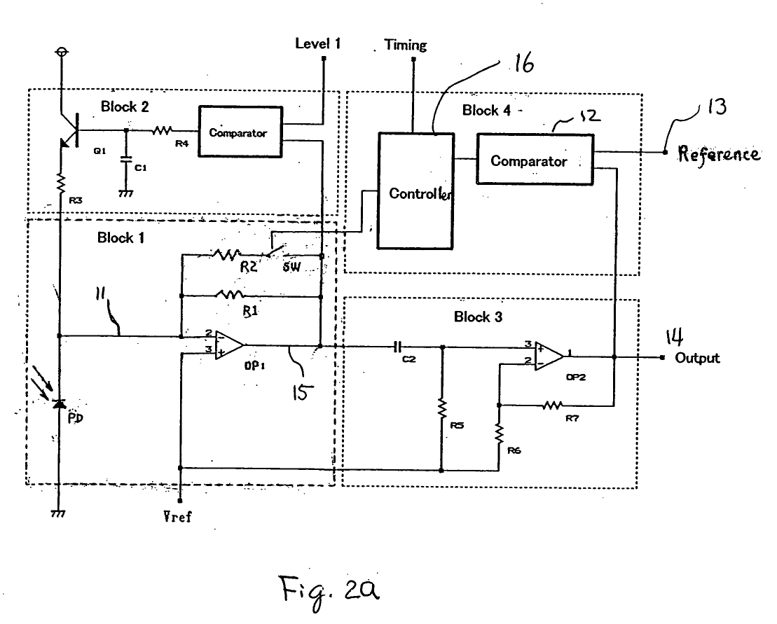

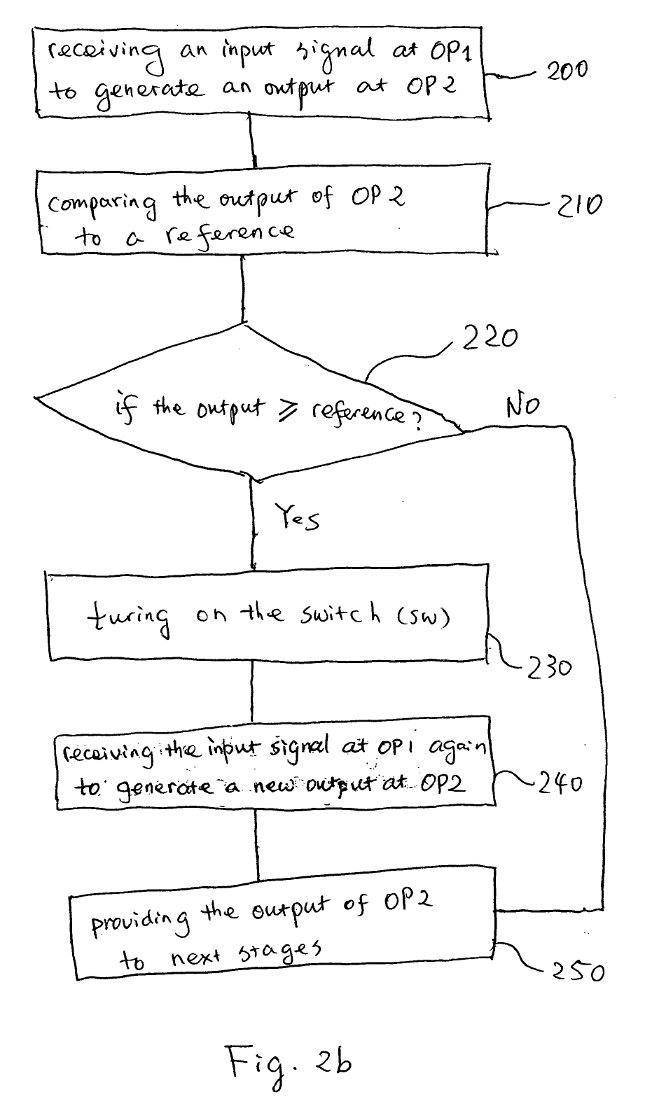

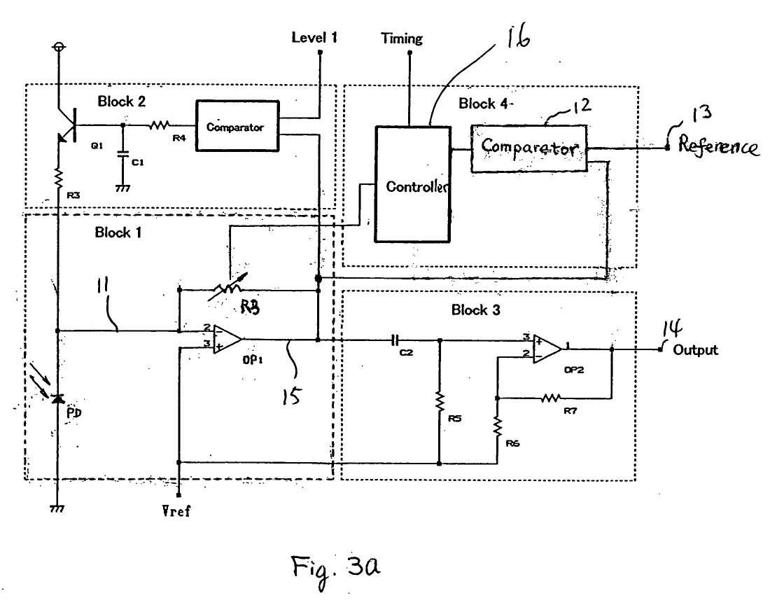

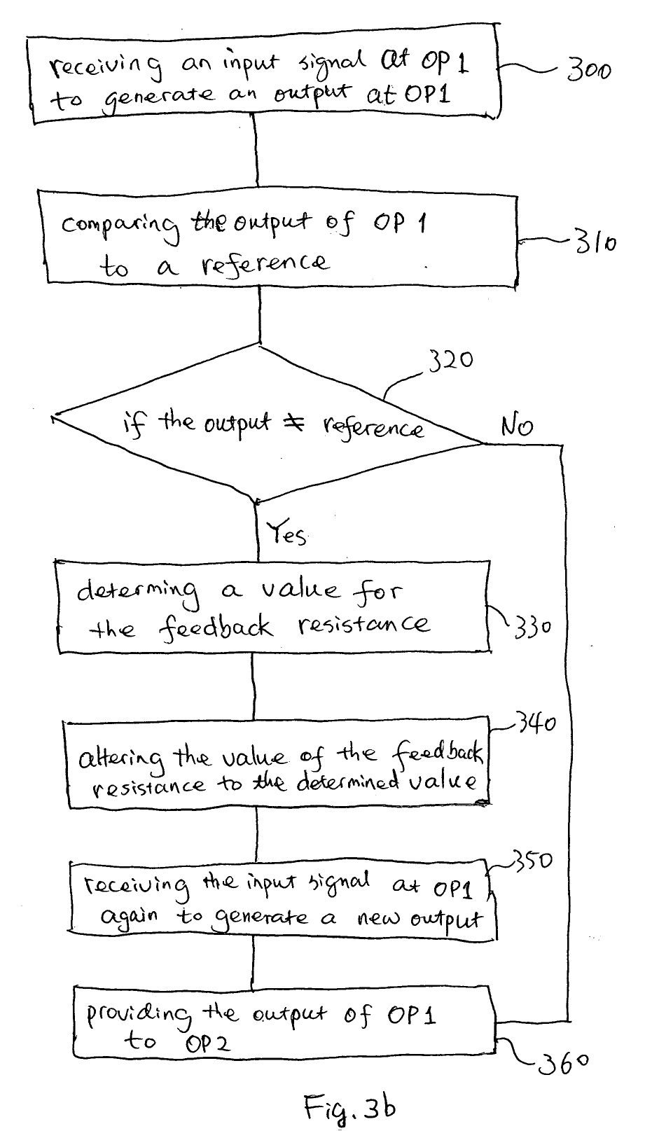

The preferred embodiments of the preamplifier circuit according to the present invention are shown in FIGS. 2a and 3a, and their operations are illustrated in FIGS. 2b and 3b. Similar references are used throughout the drawings to indicate similar elements.

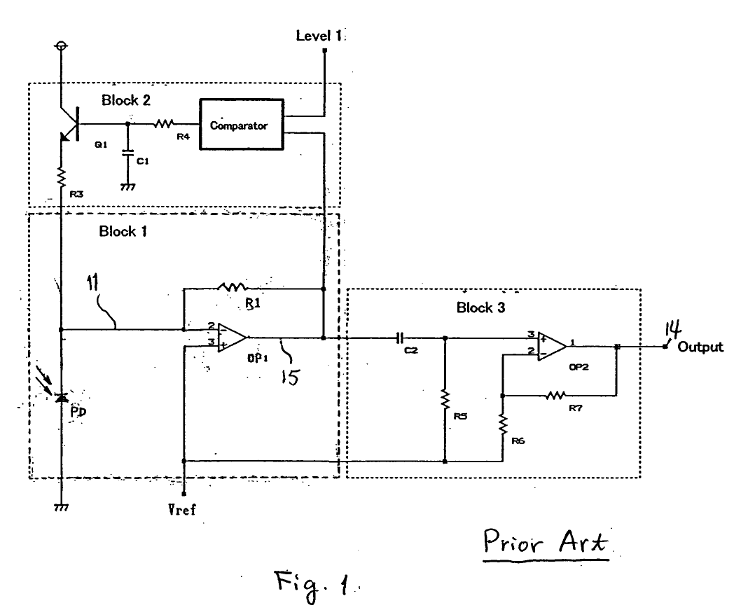

FIG. 2a illustrates a first preferred embodiment of the two-stage preamplifier circuit according to the present invention, which comprises four blocks of circuits. The circuits in Blocks 1 and 3 are the same as those in the prior art preamplifier circuit as shown in FIG. 1, and thus will not be explained further.

The circuit in Block 1 is different from that shown in FIG. 1 in that the feedback resistance comprises not only the resistor R1 which is connected to the first stage amplifier OP1 in parallel, but also another resistor R 2 that is connected to resistor R1 in parallel through a normally-off switch SW. Thus, the value of the feedback resistance can be selected from a larger one (when the switch SW is turned off) and a smaller one (when the switch SW is on).

Block 4 is a control circuit for controlling the switch SW to be turned on or off. More specifically, an output 14 of the second stage amplifier OP2 in Block 3, which is generated by amplifying the output 15 of amplifier OP1, is provided to a comparator 12 in the control circuit (Block 4). The comparator 12 compares the output 14 with a reference signal 13 and provides a result to the controller 16, which in response turns on or off the switch SW of resistor R2.

The reference signal 13 has a predetermined value at which the output 14 of the amplifier OP2 is saturated. When the result from the comparator 12 indicates that the output 14 reaches, or is larger than, the value of the reference signal 13, the controller 16 turns on the switch SW to connect the resistor R2 in parallel with the resistor R1 to lower the value of the feedback resistance, thus decreasing the gain of the amplifier OP1. Consequently, the output 15, which is an input to the amplifier OP 2, is also decreased, and the output 14 of amplifier OP2 is therefore lowered to below the saturation level.

The operation of the two-stage preamplifier circuit shown in FIG. 2a is described below with reference to FIG. 2b. At step 200, the preamplifier circuit receives an input signal 11 at the first stage amplifier OP1 and generates an output 14 at the second stage amplifier OP2. As shown in FIG. 2a, the input signal 11 may be generated by the photodiode PD from a light input signal, such as a barcode reader or scanner. The output 15 of the first stage amplifier OP1 is provided as an input signal to the second stage amplifier OP2 to generate the final output 14 of the preamplifier circuit. At step 210, the output 14 from the amplifier OP2 is provided to the comparator 12 to be compared to a reference signal 13, and a result is obtained at step 220 as to whether the output 14 is below the reference signal 13 (which is preferably equal to the saturation level of the amplifier OP2). If the output 14 is lower than the reference signal 13, the output 14 is provided to next stages at step 250 for further processing. If the output 14 is found to be equal to, or larger than, the reference signal 13 (and therefore is saturated), the switch SW is turned on by the controller 16 at step 230, thus changing the feedback resistance from a larger value to a smaller value. After the switch SW is on, the first stage amplifier OP1 receives the input signal 11 again and a new output 14, is generated, at step 240. This may be done, for example, by scanning the barcode again. At step 250, the new output 14 is provided to next stages for further processing.

Thus, when the input signal 11 is relatively small, such as when the scanner is at a distance from the barcode, the output 14 is below the saturation level. With the switch SW normally off, the feedback resistance only comprises the first resistor R1 and therefore assumes a larger value. This results in a higher signal-to-noise (SN).

When the scanner is close to the barcode, a large photocurrent is generated as the input signal 11 to the amplifier OP1. If it is too large for the amplifiers to process, the switch SW is automatically turned on to connect the second resistor R2 with the resistor R1 in parallel to decrease the feedback resistance and consequently thus the gain of the amplifier OP1 so that the output 14 of amplifier OP2 is lowered to below the saturation level. Even though the decrease in the feedback resistance will increase the noise, such a situation only occurs when the input signal is high, and hence, an acceptable signal noise ratio is achieved.

Typically, although not necessarily, a first scan cycle is used to adjust the resistance, and subsequent scan cycles are used to actually read the data. Thus, after a first scan, the additional resistance is switched in or out of the circuit as may be necessary.

FIG. 3 illustrates another preferred embodiment according to the present invention. In this embodiment, instead of using two parallel resistors R1 and R2, the feedback resistance comprises a single variable resistor R3 which is controlled by a controller 16 to change in value. The output 15 of the first stage amplifier OP1 is used to control the changing of the variable resistor R3. More specifically, the output 15 is provided to the comparator 12 to be compared to a reference signal 13.

Preferably, the value of the reference signal 13 is equal to a predetermined acceptable maximum value of the output 15 of the amplifier OP1, which is below the saturation level of amplifier OP1 and will not result in a saturated output 14 at the next stage amplifier OP2. The comparator 12 decides whether the output 15 of the amplifier OP1 is substantially equal to the reference signal 13, and the result is provided to the controller 16. The controller 16 may be a microprocessor which comprises an algorithm for determining a new value for the variable resistor R3 with which the output 15 will be equal to the reference signal 13 at the same input signal 11. After the new value is determined, the controller 16 sends a control signal to the variable resistor R3 to alter it to the newly determined value.

The operation of the preamplifier circuit shown in FIG. 3a is now described as follows. At step 300, the first stage amplifier OP1 receives an input signal 11 to generate an output 15 of the amplifier OP1. The input signal 11 may be a photocurrent generated by a photodiode PD in a scanner from a light input reflected from a barcode. The output 15 of amplifier OP1 is provided to the comparator 12 to be compared to the reference signal 13 at step 310. If the output 15 is equal to the reference signal 13, the output 15 is provided to the second stage amplifier OP2 for processing. If the output 15 is not equal to the reference signal 13, the controller 16 will determine, by running an appropriate algorithm, a new value for the variable resistor R3, at step 330. At step 340, the controller 16 sends a command signal to the variable resistor R3 to alter the value of the resistor R3 to the determined new value. Then, at step 350, the amplifier OP1 receives the input signal 11 again, which may be done by scanning the barcode at substantially the same distance again, to generate a new output 15 which will be substantially equal to the predetermined maximum output of the amplifier OP1. The new output 15 is then processed by the second stage amplifier OP2 at step 360.

With this embodiment, the variable resistor R3 may always be adjusted to a value that will generate a predetermined maximum value of the output 15. More specifically, if the output 15 is larger than the acceptable maximum value (e.g., when it is saturated), the resistor R3 and therefore the gain of the amplifier OP1 will be decreased so that the output 15 will be lowered to the predetermined maximum value which is below the saturation level. If the output 15 is smaller than the predetermined maximum value, the variable resistor R3 will be altered to a larger value determined by the controller 16 so that the gain of the amplifier OP1 will be increased to generate an output 15 of the predetermined maximum value, and the signal-to-noise (SN) will be increased. Thus, for each specific input signal, the variable resistor R3 may always be altered to assume an acceptable maximum value in view of the output 15, and therefore results in a substantially the highest signal-to-noise (SN) for every specific input signal.

The above has described in detail the preferred embodiments of the present invention. However, it shall be understood that, without departing the gist of the present invention, numerous variations, modifications and adaptations are readily available to a person of ordinary skill in the art. For example, one or both of the resistors in the embodiment in FIG. 2a may also be variable in value so as to finely tune the feedback resistance. The output signal that is compared with the reference signal 13 in both embodiments shown in FIGS. 2a and 3a can be either the output 14 of amplifier OP2 or the output 15 of the amplifier OP1, or can be an output anywhere proper in the preamplifier circuit. Moreover, the steps 310 and 320 in FIG. 3b may be omitted. Thus, the scope of the present invention is solely intended to be defined in the following claims.

What is claimed is:

1. A preamplifier circuit connected to an output of a photodiode, comprising an amplifier for amplifying an input signal and a feedback resistance connected to said amplifier in parallel, wherein a value of said feedback resistance is controllably variable.

2. The preamplifier circuit of claim 1, wherein said value is controllable according to an output signal.

3. The preamplifier circuit of claim 2, wherein said feedback resistance comprises a first resistor and a second resistor connected to said first resistor in parallel through a switch.

4. The preamplifier circuit of claim 3, further comprises a control circuit to turn on or turn off said switch so as to connect or disconnect said second resistor to said first resistor.

5. The preamplifier circuit of claim 4, wherein said switch is turned on only when said output signal reaches a predetermined value.

6. The preamplifier circuit of claim 5, wherein said control circuit comprises a comparator for comparing said output signal with said predetermined value.

7. The preamplifier circuit of claim 3, wherein said switch is a bipolar transistor or an FET.

8. The preamplifier circuit of claim 1, wherein said feedback resistance comprises a variable resistor.

9. The preamplifier circuit of claim 8, further comprising a control circuit for altering said value of said variable resistor so as to change a gain of said amplifier such that said output signal will be substantially equal to a predetermined maximum value.

10. The preamplifier circuit of claim 2, wherein said output signal is an output of said amplifier, or an output of another amplifier for amplifying said output of said amplifier.

11. A method for amplifying an input signal in a preamplifier circuit having an amplifier and a feedback resistance, comprising the steps of:
receiving said input signal at said amplifier to generate a first output signal;
comparing said first output signal with a reference to decide whether said first output signal meets a predetermined requirement;
if not, altering a value of said feedback resistance and receiving said input signal at said amplifier again to generate a second output signal.

12. The method of claim 11, wherein said predetermined requirement is that said first output signal be smaller than said reference.

13. The method of claim 12, wherein said altering comprises changing said value of said resistance from a larger value to a smaller value.

14. The method of claim 13, wherein said feedback resistance comprises a first resistor and a second resistor connected to in parallel to said first resistor through a switch, and wherein said altering comprises turning on said switch so as to connect said second resistor to said first resistor.

15. The method of claim 14, wherein said switch is normally off.

16. The method of claim 11, wherein said predetermined requirement is that said first output signal is substantially equal to said reference.

17. The method of claim 16, wherein said altering comprises changing said value of said feedback resistance such that said second output signal will be substantially equal to said reference for said input signal.

18. The method of claim 11, wherein said first and second output signals are outputs of said amplifier.

19. The method of claim 11, wherein said preamplifier circuit further comprises an another amplifier for amplifying an output of said amplifier, and said first and second output signals are outputs of said another amplifier.

20. The method of claim 11, wherein said reference is a maximum non-saturated value of said amplifier.

21. An optical receiving device for generating an electrical output signal from an optical input signal comprising:
A photo detector for receiving said optical input signal and generating a corresponding photocurrent,
a preamplifier circuit for converting said photocurrent into an output voltage;
wherein said preamplifier circuit comprises an amplifier for amplifying said photocurrent and a feedback resistance connected to said amplifier in parallel, and a value of said feedback resistance is controllably variable.

22. The optical receiving device of claim 21, wherein said feedback resistance comprises a first resistor and a second resistor connected to said first resistor in parallel through a switch.

23. The optical receiving device of claim 22, further comprising a control circuit for turning on said switch when an output signal reaches a predetermined threshold.

24. The optical receiving device of claim 21, wherein said photo detector is a photodiode.

25. The optical receiving device of claim 21, wherein it is a barcode reader or scanner.

26. A method for amplifying an input signal in a preamplifier circuit having an amplifier and a feedback resistance, comprising the steps of:
a) receiving said input signal at said amplifier to generate an output signal;
b) determining a value for said feedback resistance at which said output signal will be substantially equal to a predetermined value if said input signal remains unchanged; and
c) altering said feedback resistance to said determined value and receiving said input signal at said amplifier again to generate a new output signal.

27. The method of claim 26, wherein said predetermined value is a predetermined maximum value of said output signal.

28. The method of claim 27, wherein said output signal is an output of said amplifier.

29. The method of claim 28, wherein said feedback resistance comprises a variable resistance controlled by a control circuit.

30. The method of claim 29, further comprising a step of comparing said output signal to said predetermined value, and if they are equal, omitting said step c).
